(19) United States
(12) Patent Application Publication
(10) Pub. No.: US 2016/0181382 A1
(43) Pub. Date: Jun. 23, 2016

(54) METHOD FOR FABRICATING A TRANSISTOR WITH A RAISED SOURCE-DRAIN STRUCTURE

(71) Applicants: STMicroelectronics SA, Montrouge (FR); STMicroelectronics (Crolles 2) SAS, Crolles (FR)

(72) Inventors: Didier Dutartre, Meylan (FR); David Barge, Grenoble (FR)

(73) Assignees: STMICROELECTRONICS SA, Montrouge (FR); STMICROELECTRONICS (CROLLES 2) SAS, Crolles (FR)

(21) Appl. No.: 14/577,656

(22) Filed: Dec. 19, 2014

(51) Int. Cl. H01L 29/417; H01L 29/66; H01L 29/786; H01L 29/10

(52) U.S. Cl. CPC H01L 29/41783; H01L 29/1037; H01L 29/1079; H01L 29/6656; H01L 29/78603

(57) ABSTRACT

A method for forming a transistor includes defining agate structure on a top surface of a first semiconductor layer of a silicon-on-insulator (SOI) substrate. The gate structure includes an insulating cover. A second semiconductor layer is then conformally deposited. The deposited second semiconductor layer includes an epitaxial portion on surfaces of the first semiconductor layer and an amorphous portion on surfaces of the insulating cover. The amorphous portion is then removed using a selective etch. The remaining epitaxial portion forms faceted raised source-drain structures on either side of the transistor gate structure. A slope of the sloped surface for the facet is dependent on the process parameters used during the conformal deposition.

### TECHNICAL FIELD

This disclosure relates generally to integrated circuits, and more particularly, to the fabrication of a MOSFET device on a substrate of the silicon-on-insulator (SOI) type, and especially on a substrate of the fully-depleted silicon-on-insulator (FD-SOI) type.

### BACKGROUND

A substrate of the silicon-on-insulator (SOI) type comprises a semiconductor film or layer, for example of silicon or of an alloy of silicon, for example a silicon-germanium alloy, situated on top of a buried insulating layer, commonly denoted under the acronym BOX (Buried-OXide), which is itself situated on top of a carrier substrate, for example a semiconductor well or layer.

In a fully depleted silicon-on-insulator (FD-SOI) technology, the semiconductor film is totally depleted; in other words, it is composed of intrinsic semiconductor material. The thickness of the fully depleted film is generally of the order of a few nanometers. Furthermore, the buried insulating layer is itself generally very thin, of the order of ten nanometers.

In view of the limited thickness of the semiconductor film, which is used to form the channel region of the transistor, the source and drain regions of the MOSFET device comprise portions that are raised (or elevated) with respect to the semiconductor film. This permits the making of a suitable electrical connection between these regions and the channel region of the transistor. Such raised source and drain (RSD) regions are typically obtained by epitaxial growth. The conventional epitaxial growth process implements either intrinsic silicon combined with a subsequent implantation of dopants or a doped epitaxy in situ.

These epitaxially-grown regions, on one hand, must be situated as close as possible to the channel in order to reduce the effective gate length and lower access resistance, but, on the other hand, must be situated as far as possible from the edges of the gate in order to reduce the lateral stray capacitance. These competing interests make the formation of the raised source and drain regions with appropriate shapes a critical and costly point in the method of transistor fabrication.

Currently, faceted raised source and drain regions are desired. The term “faceted” refers to a shape of the RSD region having an inclined profile (sloped surface) adjacent the transistor gate. With this inclined shape, the distance between the source or drain region and the corresponding lateral flank of the gate region increases between the lower part of the epitaxially-grown region and the upper part of the epitaxially-grown region.

In a known configuration for making a faceted shape, successively deposited layers may be used to form the lateral insulating regions disposed on the flanks of the gate region. The combination of these multilayer lateral insulating regions and faceted epitaxial regions leads to increased fabrication costs that are prohibitive. Furthermore, the lateral insulating region near the faceted epitaxial source or drain region may be exposed to a final etch which can lead to a local thinning of the channel and consequent degradation of the electrical behavior of the transistor.

In view of the foregoing, a need exists in the art for improved methods for making faceted RSD structures.

### SUMMARY

In an embodiment, a method comprises: forming a transistor gate structure on a top surface of a first semiconductor layer of a silicon-on-insulator (SOI) substrate, wherein the gate structure includes an insulating cover; conformally depositing a second semiconductor layer, wherein the second semiconductor layer has an epitaxial portion on surfaces of the first semiconductor layer and an amorphous portion on surfaces of the insulating cover; and selectively etching to remove the amorphous portion leaving the epitaxial portion to form faceted raised source-drain structures on either side of the transistor gate structure.

In an embodiment, an integrated circuit transistor comprises: a silicon-on-insulator (SOI) substrate including a first semiconductor layer; a transistor gate structure on a top surface of the first semiconductor layer, wherein the gate structure includes an insulating cover; and faceted raised source-drain structures on either side of the transistor gate structure formed from a conformal deposit of a second semiconductor layer having an epitaxial portion on surfaces of the first semiconductor layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1-6 illustrate process steps for the fabrication of a transistor having a faceted raised source-drain structure; and

FIGS. 7-9 are scanning electron microscope images.

### DETAILED DESCRIPTION OF THE DRAWINGS

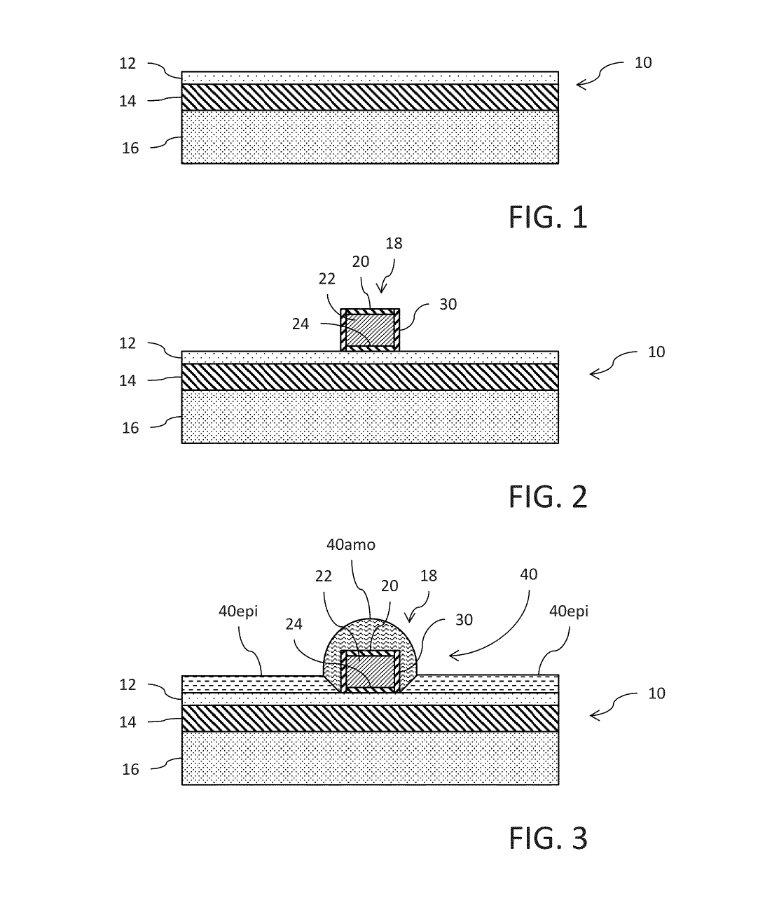

Reference is now made to FIGS. 1-6 which illustrate process steps for the fabrication of a transistor (for example, a planar MOSFET) having a faceted raised source-drain structure.

The process starts with a substrate 10 of the silicon-on-insulator (SOI) type as shown in FIG. 1. In an embodiment, the substrate 10 may be of the fully-depleted silicon-on-insulator (FD-SOI) type. The substrate 10 comprises a semiconductor layer 12 typically having a thickness on the order of a few nanometers (for example, 1-10 nanometers, and more preferably between 2-8 nanometers). The layer 12 may comprise any suitable semiconductor including, but not limited to Si, strained Si, SiC, SiGe, SiGeC, Si alloys, Ge, Ge alloys, GaAs, InAs, and InP, or any combination thereof. The layer 12 may be thinned to a desired thickness by planarization, grinding, wet etch, dry etch, oxidation followed by oxide etch, or any combination thereof. Options for SOI substrates include extremely thin silicon-on-insulator (ETSOI) and ultra-thin body and BOX (UTBB) substrates as known to those skilled in the art.

The layer 12 is situated on a buried oxide (BOX) layer 14. The buried oxide may, for example, comprise silicon dioxide.

The layer 14 is situated on a carrier substrate 16. The substrate 16 may be a semiconducting material including, but not limited to Si, strained Si, SiC, SiGe, SiGeC, Si alloys, Ge, Ge alloys, GaAs, InAs, InP as well as other III/V and II/VI compound semiconductors. The substrate 16 may, if desired, be doped for the application.

FIG. 2 depicts a gate structure 18 formed directly on the semiconductor layer 12. The gate structure 18 can be formed using deposition, photolithography and a selective etching process. Specifically, a pattern is produced by applying a photoresist to the surface to be etched; exposing the photoresist to a pattern of radiation; and then developing the pattern into the photoresist utilizing a resist developer. Once the patterning of the photoresist is completed, the sections covered by the photoresist are protected while the exposed regions are removed using a selective etching process that removes the unprotected regions.

In one embodiment, a hard mask (hereafter referred to as a dielectric cap 20) may be used to form the gate structure 18. The dielectric cap 20 may be formed by first depositing a dielectric hard mask material, like SiN or SiO₂, atop a layer of gate electrode material and then applying a photoresist pattern to the hard mask material using a lithography process steps. The photoresist pattern is then transferred into the hard mask material using a dry etch process forming the dielectric cap 20. Next, the photoresist pattern is removed and the dielectric cap 20 pattern is then transferred into the gate electrode material during a selective etching process. Alternatively, the gate structure 18 can be formed by other patterning techniques such as spacer image transfer.

The gate structure 18 may include at least a gate conductor 22 on a gate dielectric 24. The gate electrode materials used for the gate conductor 22 may, for example, comprise a metal gate electrode material formed, for example, by a conductive metal such as W, Ni, Ti, Mo, Ta, Cu, Pt, Ag, Au, Ru, Ir, Rh, and Re, and alloys that include at least one of the aforementioned conductive elemental metals. Alternatively, the gate electrode materials used for the gate conductor 22 may comprise a doped semiconductor material, such as a doped silicon containing material, for example, doped polysilicon. A top of the gate conductor 22 is covered by the dielectric cap 20 and the sidewalls are exposed during the patterned etch.

The gate dielectric 24 between the gate electrode and the layer 12 may comprise a dielectric material, such as SiO₂, or alternatively a high-k dielectric, such as oxides of Hf, Ta, Zr, Al or combinations thereof. In another embodiment, the gate dielectric 24 may comprise an oxide, such as SiO₂, HfO₂, ZrO₂, Ta₂O₅ or Al₂O₃. In one embodiment, the gate dielectric 24 has a thickness ranging from 1 nm to 10 nm. In another embodiment, the gate dielectric 24 has a thickness ranging from 1.5 nm to 2.5 nm.

A set of spacers 30 are formed in direct contact with sidewalls of the gate structure 18. The spacers 30 are typically narrow having a width ranging from 2.0 nm to 15.0 nanometers. The spacers 30 are, for example, formed using a deposition and etch processing technique where a layer of dielectric material, such as nitride, oxide, oxynitride, or a combination thereof, is conformally deposited and then preferentially etched to leave material in place on the sidewalls and remove material from the top surface of the layer 12. The thickness of the spacer 30 is pertinent to the proximity of the to-be-formed raised source-drain (RSD) regions to the channel of the device, and thus it is preferred that the spacers 30 be as thin as possible. The spacers 30 form a sidewall insulating structure for the gate structure.

It will be understood that the cap 20 need not be made of a dielectric or insulating material, the disclosure of SiN or SiO₂ being just example materials known for use in the etching process to define the gate structure 18. A metallic hard mask material could alternatively be used for the cap. Indeed, in the context of the disclosed method, what is important is the selection of materials for the cap 20 and spacers 30 which would ensure amorphous growth in the area of the gate as will be described next.

Reference is now made to FIG. 3. A non-selective deposition of a semiconductive material layer 40 is then made. This deposition is conformal. The deposited material may comprise, for example, silicon, silicon-carbon or silicon-germanium alloys. By controlling the deposition parameters, the layer 40 is formed epitaxial (mono-crystalline) in region 40epi on the exposed top surface of the layer 12 and amorphous in region 40amo on the exposed surfaces of the sidewalls 30 and cap 20. In this regard, the epitaxial growth for region 40epi occurs by expanding from the existing crystal lattice of the layer 12, while the amorphous growth for region 40amo occurs because the sidewalls 30 and cap 20 lack a lattice that could support the growth of a crystalline film. If desired, the layer 40 may be in situ doped with electrically active impurities as needed for the application. Specific details of the deposition process and its parameters are provided below.

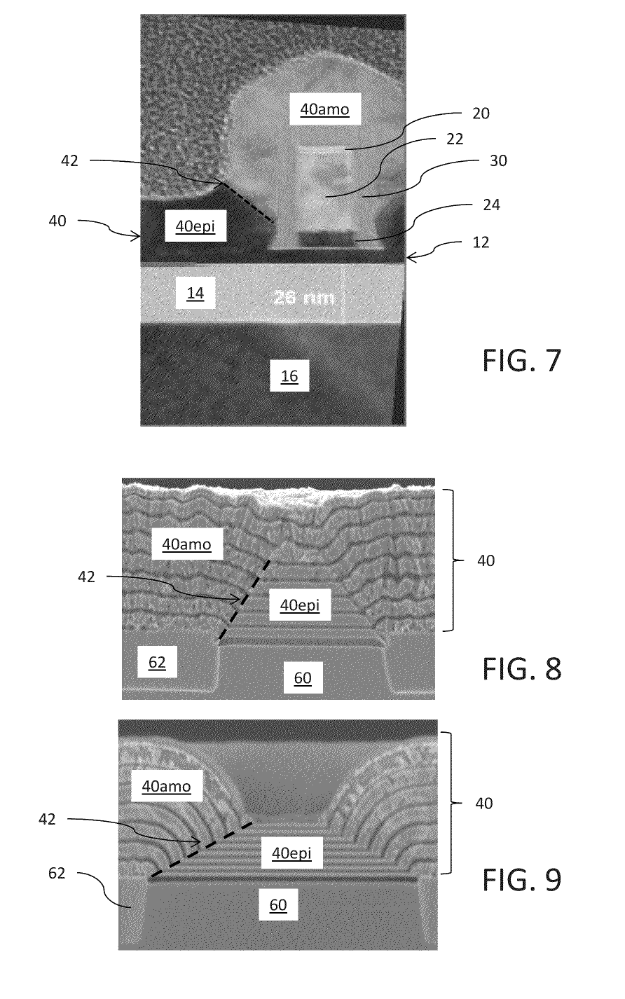

FIG. 7 shows a scanning electron microscope (SEM) image of a cross section of an integrated circuit at the point of the fabrication process shown in FIG. 3.

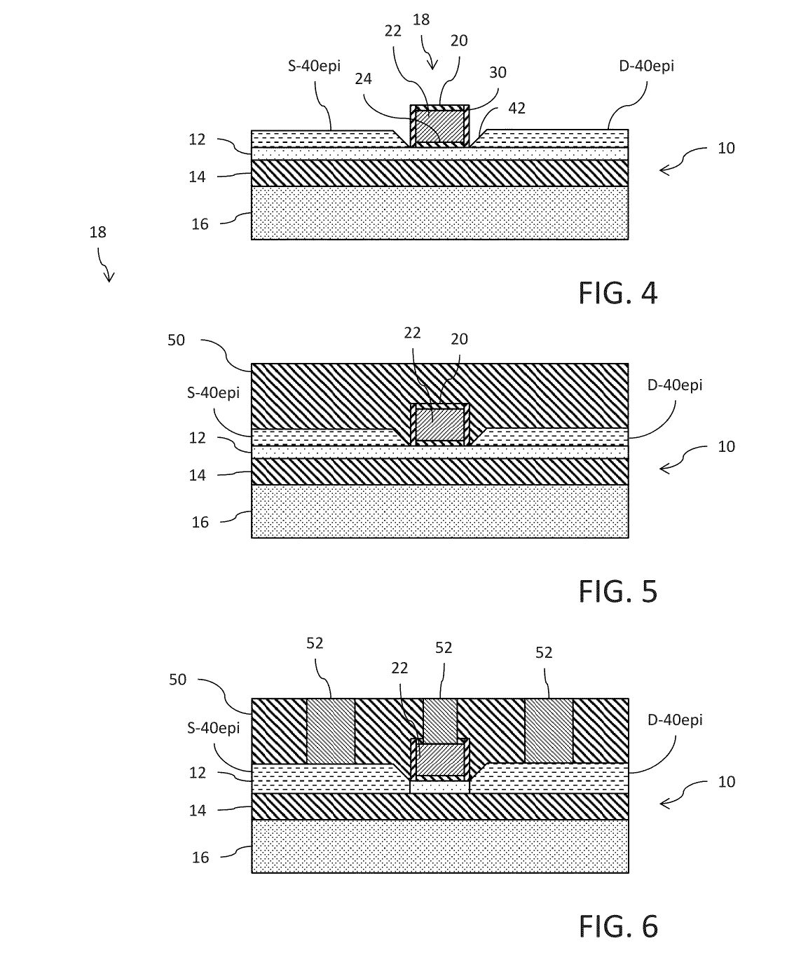

In FIG. 4, a selective etch is then performed to remove the amorphous region 40amo of the layer 40. This selective etch does not have an adverse effect on the epitaxial region 40epi of the layer 40. The result leaves a raised source region (S-40epi) and a raised drain region (D-40epi) on the top surface of the layer 12 adjacent the gate structure 18. The raised source-drain regions further exhibit a faceted shape with a sloped surface 42 where the distance between the source or drain region and the corresponding lateral flank of the gate region increases from the lower part to the upper part of the epitaxial 40epi growth portion. As an example, the selective etch may comprise: a thermal treatment that can be processed in an epitaxy tool using a HCl or a Cl₂ gas chemistry, with partial pressures of 66 Torr and 133 Torr for HCl and H (carrier gas), respectively, for one minute and at a temperature between 620° C. and 700° C. These conditions correspond to a selective etch adapted to a 20-30 nm-thick epitaxy of silicon, and the temperature has to be decreased for SiGe as will be understood by a skilled in the art.

In FIG. 5, a pre-metal dielectric layer 50 is deposited and planarized.

In FIG. 6, openings are formed in the layer 50 over the raised source S, raised drain D and gate 22, with the openings filled with a contact metal 52, for example, tungsten.

FIG. 6 further shows a distinction between the source-drain regions and the channel region of the transistor. This distinction arises as a result of the deposition and diffusion of dopants with respect to the formation of the RSD structures.

The fabricated transistor may comprise either an n-channel device or a p-channel device. The process further supports CMOS circuit fabrication as the process technique can be provided with suitable mask offs to fabricate both n-channel and p-channel devices on a common substrate 10.

The value of the slope for the sloped surface 42 of the faceted raised source-drain structures may be controlled varying the process parameters for the non-selective deposition of the semiconductive material layer 40 (FIG. 3). In particular, the morphology of the crystalline phase forming the epitaxial region 40epi is tunable by adjusting the process conditions. For example, use of a relatively higher temperature during the deposition produces a relatively higher slope value. Conversely, use of a relatively lower temperature during the deposition process produces a relatively lower slope value.

FIGS. 8 and 9 are scanning electron microscope (SEM) images of a cross section of an integrated circuit including a semiconductor (silicon) region 60 and an adjacent insulating (silicon dioxide) region 62 which has been subjected to a non-selective deposition of a semiconductive material layer 40. It will be noted that, in FIGS. 8 and 9, silicon-germanium (Si—Ge) layers have been interleaved with silicon layers during the epitaxial growth, and a chemical revealing technique has been applied to the TEM lamella (SiGe selective etch) in order to show the growth kinetic of epitaxial and amorphous phases.

The process parameters which follow are used for depositing the bulk of the non-selective deposition of a semiconductive material layer 40, and does not account for the intermediate layers used and are provide as an example only. The process parameters for the non-selective deposition used in FIG. 8 comprise: a SiH₄/H₂ chemistry with a SiH₄ partial pressure of 0.85 Torr and a temperature of 720° C. The process parameters for the non-selective deposition used in FIG. 9 comprise: a SiH₄/H₂ chemistry with a SiH₄ partial pressure of 0.85 Torr and a temperature of 590° C.

It will be noted that the slope value of the surface 42 between the epitaxial region 40epi of the layer 40 and the amorphous region 40amo of the layer 40 is greater in FIG. 8 than in FIG. 9. In this case, the only difference in process condition is temperature. Thus, use of a relatively higher temperature during the deposition produces a relatively higher slope value for the surface 42.

Besides the temperature, other process parameters may be adjusted for the purpose of tuning the morphology of the crystalline phase and setting the slope value. As an example, the manipulation of the deposition kinetics will modify the slope value: taking a more reactive Si precursor or using a higher partial pressure of the precursor at a given temperature will increase the kinetics and produce a smaller slope.

An advantage of the present process is that it is suitable for the fabrication of faceted RSD structures for any crystal orientation of the substrate layer 12.

As discussed above, another advantage of the present process is that it permits selecting of the slope value for the facet surface by making adjustments to the process conditions for the non-selective deposition of a semiconductive material layer 40. Indeed, it will further be understood that the slope value can be varied during the deposition of layer 40 by changing the process conditions. Alternatively, an intermediate (partial) etch may be introduced into the non-selective deposition in order to effectuate a slope change.

A further advantage of the present process is a reduction in cost. In this regard, the present process obviates the requirement of prior art faceted RSD fabrication processes for lithographic steps associated with facet definition.

Yet another advantage of the present process is its applicability to a number of different transistor types (planar MOSFET and FINFET) as well as to a number of different technology nodes (14 nm, 28 nm, etc.) and still further to a number of different substrate types.

It will be readily understood by those skilled in the art that materials and methods may be varied while remaining within the scope of the present disclosure. It is also appreciated that the present disclosure provides many applicable inventive concepts other than the specific contexts used to illustrate embodiments. Accordingly, the appended claims are intended to include within their scope such processes, machines, manufacturing, compositions of matter, means, methods, or steps.

What is claimed is:

1. A method, comprising:
forming a transistor gate structure on a top surface of a first semiconductor layer of a silicon-on-insulator (SOI) substrate, wherein the transistor gate structure includes sidewall spacers and a cover;
conformally depositing a second semiconductor layer, wherein the second semiconductor layer has an epitaxial portion on surfaces of the first semiconductor layer and an amorphous portion on surfaces of the sidewall spacers and cover; and
selectively etching to remove the amorphous portion leaving the epitaxial portion to form faceted raised source-drain structures on either side of the transistor gate structure.

2. The method of claim 1, wherein the SOI substrate comprises a fully depleted (FD) SOI substrate.

3. The method of claim 1, wherein the SOI substrate comprises an ultra-thin body and BOX (UTBB) substrate.

4. The method of claim 1, wherein the SOI substrate comprises an extremely thin silicon-on-insulator (ETSOI) substrate.

5. The method of claim 1, wherein an interface between the epitaxial portion and the amorphous portion is a sloped surface.

6. The method of claim 5, further comprising choosing process parameters for the deposition of the second semiconductor layer to set a slope value for the sloped surface.

7. The method of claim 6, further comprising introducing an intermediate etch in the deposition of the second semiconductor layer to adjust the slope value.

8. The method of claim 5, further comprising adjusting process parameters during the deposition of the second semiconductor layer to change a slope value for the sloped surface.

9. The method of claim 5, further comprising setting a temperature of the deposition process to set a slope value for the sloped surface, wherein a relatively higher temperature produces a relatively higher slope value and a relatively lower temperature produces a relatively lower slope value.

10. An integrated circuit transistor, comprising:
a silicon-on-insulator (SOI) substrate including a first semiconductor layer;
a transistor gate structure on a top surface of the first semiconductor layer, wherein the gate structure includes an insulating cover; and
faceted raised source-drain structures on either side of the transistor gate structure formed from a conformal deposit of a second semiconductor layer having an epitaxial portion on surfaces of the first semiconductor layer.

11. The transistor of claim 10, wherein the conformal deposit further includes an amorphous portion on surfaces of the insulating cover.

12. The transistor of claim 11, further comprising an interface between the epitaxial portion and the amorphous portion defined as a sloped surface.

13. The transistor of claim 10, wherein the faceted raised source-drain structures have a sloped surface having a slope value, and wherein the slope value is dependent on at least one process parameter of the conformal deposit of the second semiconductor layer.

14. The transistor of claim 13, wherein the process parameter is temperature.

15. The transistor of claim 10, wherein the SOI substrate comprises a fully depleted (FD) SOI substrate.

16. The transistor of claim 10, wherein the SOI substrate comprises an ultra-thin body and BOX (UTBB) substrate.

17. The transistor of claim 10, wherein the SOI substrate comprises an extremely thin silicon-on-insulator (ETSOI) substrate.

18. A method, comprising:
forming a transistor gate structure on a top surface of a first semiconductor layer of a silicon-on-insulator (SOI) substrate;
conformally depositing a second semiconductor layer, wherein the second semiconductor layer has an epitaxial portion on surfaces of the first semiconductor layer and an amorphous portion over the transistor gate structure; and
selectively etching to remove the amorphous portion leaving the epitaxial portion to form faceted raised source-drain structures on either side of the transistor gate structure.

19. The method of claim 18, wherein an interface between the epitaxial portion and the amorphous portion is a sloped surface.

20. The method of claim 19, further comprising choosing process parameters for the deposition of the second semiconductor layer to set a slope value for the sloped surface.
